(19) United States
(12) Patent Application Publication
(10) Pub. No.: US 2016/0181498 A1
(43) Pub. Date: Jun. 23, 2016

(54) Enhanced Power Conversion Efficiency from Thermoelectric Metamaterials

(71) Applicant: Loyola University New Orleans, New Orleans, LA (US)

(72) Inventor: Patrick Louis Garrity, New Orleans, LA (US)

(73) Assignee: LOYOLA UNIVERSITY NEW ORLEANS, New Orleans, LA (US)

(21) Appl. No.: 14/213,601

(22) Filed: Mar. 14, 2014

Related U.S. Application Data
(60) Provisional application No. 61/787,007, filed on Mar. 15, 2013.

(51) Int. Cl. H01L 35/28

(52) U.S. Cl. CPC H01L 35/28

(57) ABSTRACT

A thermoelectric metamaterial is provided, comprising a plurality of component materials selected from the group consisting of dielectrics, semiconductors, semimetals, and metals. The component materials are placed into contact with one another and arranged in a selected geometrical configuration adapted to achieve a thermal conductivity of the metamaterial that is different from the thermal conductivity of each of the component materials. Specifically, the component materials are arranged to affect an increase in the figure of merit and power conversion efficiency of the metamaterial. The thermoelectrical properties of the metamaterial may be adjusted to suit a desired application by changing one or more attributes, including: (a) one of the component materials, (b) the geometric configuration of the component materials, (c) the volume of one or more of the component materials, (d) the absence of a component material at a selected location within the metamaterial, and (e) the manner of contact between the component materials.

### CROSS-REFERENCE TO RELATED APPLICATIONS

This application claims the benefit under 35 U.S.C. §119(e) to provisional application Ser. No. 61/787,007, filed Mar. 15, 2013.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### BACKGROUND OF THE INVENTION

1. Field of the Invention

The present invention relates to achieving increased power conversion efficiency from the use of thermoelectric metamaterials, and more particularly to such metamaterials that can be formed or assembled in specific geometric configurations that are optimized for certain applications.

2. Description of Related Art

Approximately 60% of energy produced in the United States is wasted in the form of heat. Industrial applications, automobiles and commercial/residential heating systems all generate an enormous amount of unused waste heat. Thermoelectric (TE) materials have the ability to convert heat into electricity by utilizing the Seebeck effect, where a voltage difference proportional to a temperature difference is produced when two dissimilar materials are joined together and their junctions held at different temperatures.

The phenomenon also works in reverse where a temperature difference is developed when a voltage is applied (Peltier effect). With respect to generating an output voltage, thermoelectric conversion efficiency is expressed through the dimensionless figure of merit ZT where increasing values of ZT equate to higher power conversion efficiencies. For isotropic materials, ZT=σS²T/x where Z is the figure of merit, T is temperature, σ is electrical conductivity, S is the Seebeck coefficient and x is the thermal conductivity. The power factor PF is another important thermoelectric parameter and is expressed as PF=σS². It is immediately obvious that a large power factor and small thermal conductivity will result in higher power generation efficiencies.

Research efforts often engage the power factor PF=σS² initially, which, is optimized as a function of carrier concentration through doping. Further enhancements to ZT may be attained by reducing the thermal conductivity, however TE materials facilitate heat flow through both lattice and electronic contributions to the total thermal conductivity. Starkly demonstrating the coupled transport issue, σ is usually proportional to the electronic thermal conductivity through the Wiedemann-Franz relationship.

Therefore, reductions in the electronic thermal conductivity are accompanied by proportional reductions in σ thus negating ZT enhancements. Some efforts have focused on material fabrication techniques that result in preferential lattice phonon scattering compared to electrons. This reduces the lattice contribution to thermal conductivity which is a step in the right direction because in most TE materials, phonons are the predominant heat conduction mechanism. Fundamentally, this is a form of microscopic heat conduction management, which has the potential to dramatically increase ZT. While modern thermoelectric energy conversion devices operate at a ZT of about 0.75-1.5, the ZT must be raised to approximately 4 or greater to effectively compete with other power generation methods.

This invention utilizes a new method to precisely control the flow of heat in a thermoelectric material resulting in tunable effective thermal conductivity x_{eff} properties. The method involves geometrical configurations that result in a bulk material that exhibits properties unlike any found in naturally occurring materials, i.e., a metamaterial. The host material Seebeck coefficient and electrical conductivity remain unchanged. The metamaterial configuration enables x_{eff} to be selectively lowered or raised while maintaining a constant PF that is unperturbed from the host material. When x_{eff} is lowered, the thermoelectric metamaterial exhibits high energy conversion efficiency through engineered control over the thermal transport properties. Further tuning of the transport properties result in a large figure of merit for cooling or heating applications. Consequently, the figure of merit and power generation efficiency may be substantially increased by selectively tuning the transport properties via geometrical design configurations.

The deliberate control of energetic fields and currents to produce specific selective material properties is characteristic of artificial materials or metamaterials. Metamaterials incorporate artificially combined components and should be distinguished from the widely used alloy-based processing of TE materials. Alloying entails diffusion and reaction processes that result in thermodynamically governed phases. Metamaterials are typically multi-component materials whose constituents retain their original composition and structure but may be patterned in a periodic manner. Despite the breadth of research on metamaterials (e.g., photonics, phononics, etc.), limited applications of artificial TE materials have surfaced in the literature. Several reports on the fabrication and characterization of tilted multilayer structures intended to create a transverse Seebeck response have been published, however, the research intent of these groups focused upon measurements rather than transport property manipulation. The relevant component of their work lies in the fact that they created anisotropic thermoelectric effects from carefully designed macroscopic layered structures, thus emulating crystalline materials that naturally exhibit anisotropic thermoelectric coefficients. There have also been reports on general heat flux manipulation through geometry-centric configurations, however, there have been no reports on utilizing metamaterial-based thermal management techniques to enhance the figure of merit, Z. Considering an artificial TE material subjected to a temperature difference, the induced thermal transport behavior resulting from carefully arranged materials may be contrary to expectations and more importantly, manipulated and controlled for a specific purpose.

### SUMMARY OF THE INVENTION

Therefore, in a preferred embodiment, a thermoelectric metamaterial is provided, comprising a plurality of component materials selected from the group consisting of dielectrics, semiconductors, semimetals, and metals; and wherein the plurality of component materials are placed into contact with one another and arranged in a selected geometrical configuration adapted to achieve a thermal conductivity of the metamaterial that is different from the thermal conductivity of each of the component materials.

The component materials are arranged such that the figure of merit of the metamaterial and the power conversion efficiency of the metamaterial are increased relative to the figure of merit and power conversion efficiency of each of the component materials.

In a more preferred embodiment, one of the component materials includes nanoparticles of another component material.

In a further embodiment, the geometric configuration of the component materials is rearranged to affect a change in the thermoelectrical properties of the metamaterial.

The component materials are placed into contact with one another by mechanical pressure, adhesives, or welding.

Optionally, the component materials have surfaces which are coated with another component material.

In another embodiment, the thermoelectrical properties of the metamaterial are adjusted to suit a desired application by changing one or more of the following attributes: (a) one of the component materials, (b) the geometric configuration of the component materials, (c) the volume of one or more of the component materials, (d) the absence of a component material at a selected location within the metamaterial, and (e) the manner of contact between the component materials.

The above and other objects and features of the present invention will become apparent from the drawings, the description given herein, and the appended claims.

### BRIEF DESCRIPTION OF THE DRAWINGS

For a further understanding of the nature, objects, and advantages of the present invention, reference should be had to the following detailed description, read in conjunction with the following drawings, wherein like reference numerals denote like elements.

FIG. 1 depicts a schematic diagram of a possible thermoelectric (TE) material having a particular geometric configuration.

FIG. 2 depicts a finite element result of the heat flux vector direction for the TE material of FIG. 1.

FIG. 3 depicts a finite element result of the electrical current vector direction for the TE material of FIG. 1.

FIG. 4 depicts a graph showing tower conversion efficiency as a function of load resistance for a sample material and a control material.

### DETAILED DESCRIPTION OF THE INVENTION

Before the subject invention is further described, it is to be understood that the invention is not limited to the particular embodiments of the invention described below, as variations of the particular embodiments may be made and still fall within the scope of the appended claims. It is also to be understood that the terminology employed is for the purpose of describing particular embodiments, and is not intended to be limiting. Instead, the scope of the present invention will be established by the appended claims.

In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs.

Referring now to FIG. 1, one example of a thermoelectric metamaterial configuration 1 is depicted. This configuration is only one of many possible geometrical designs. The light-colored component 2 represents the monocontinuous thermoelectric host material and the dark-colored component 3 represents the dielectric material. The geometrical design is aimed at separating the electrical and thermal currents in order to independently tune x. A direct method to accomplish such decoupling is to fabricate a two-component monocontinuous composite constructed in layered form. As depicted in FIG. 1, the monocontinuous TE host material 2 provides an uninterrupted electrical current path while an electrical insulator or dielectric (DE) material 3 layered between the TE host material 2 provides a thermally conductive path only. This configuration exploits diffusive heat flow between the TE and DE materials that is selective by blocking charge transfer yet allowing thermal current flow. By selecting a DE material with the appropriate thermal conductivity and geometrical dimensions, thermal currents develop a tensorial form and rotate at an angle θ with respect to the electrical current. From a thermal management perspective, the thermal conductance of the local TE-DE region must be larger than adjacent regions resulting in heat current diversion from the TE into the DE. Consequently, heat flows from a material with both lattice and electronic contributions (TE) into a material with lattice participation only (DE). This field-induced anisotropy places thermal resistances in series when the hot and cold sources are arranged as shown in FIG. 1.

Series thermal resistances are analyzed through summation thus leading to a total thermal resistance that may be precisely tuned and alternatively expressed by an effective thermal conductivity x_{eff}. By selecting DE materials with a smaller thermal conductivity than the TE, the metamaterial structure exhibits an effective thermal conductivity x_{eff} lower than the TE material alone. Equally important, the PF remains unchanged due to energetic neutrality of the DE with respect to electrical and thermoelectrical transport. As a result, the TE metamaterial behaves as a single material from an electrical and thermoelectrical standpoint yet responds thermally as a two-component composite.

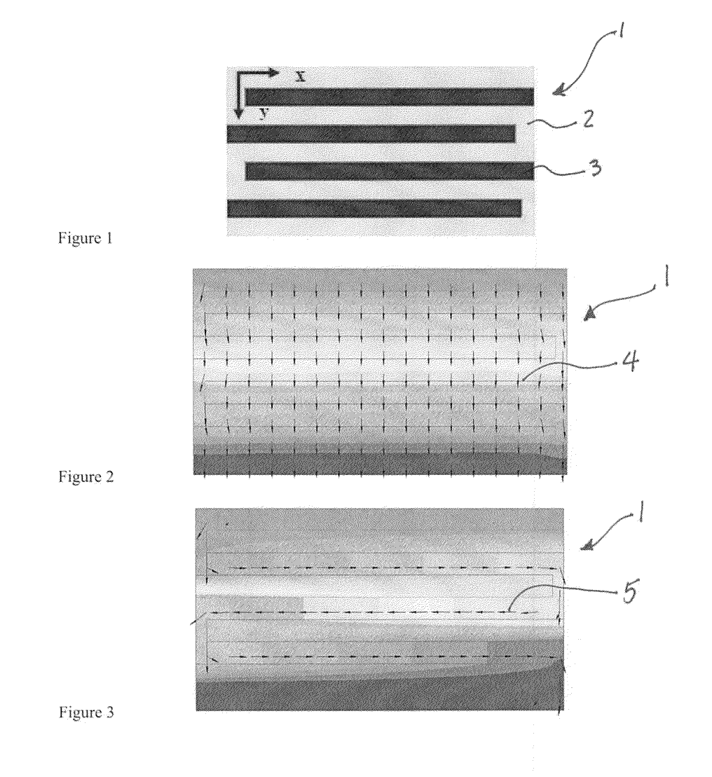

With respect to FIG. 2, finite element computational results are shown for the heat flux vector direction in the TE metamaterial of FIG. 1. In this specific example, the top of the metamaterial 1 is at 301 K while the bottom is at 300 K. The field induced anisotropy results in thermal currents directed downward rather than flowing along the thermoelectric material length. Guiding the thermal current through the low thermal conductivity dielectric layers degrades the overall thermal conductivity resulting in precise engineered control over x_{eff}. FIG. 2 also confirms that the thermal gradient 4 is approximately uniform across the material width which indicates a heat flux traveling through alternating TE-DE layers in a nearly constant manner, rather than down the length of the TE. The isotherms show little deviation when compared with the Bi₂Te₃ control sample isotherms despite the presence of DE layers that exhibit a fraction of the thermal conductivity of Bi₂Te₃. Analogous to electromagnetic cloaking, the TE acts as the “cloaked” material, barely perturbing the heat flux moving in the y-direction. As a result of geometrical design, the heat flux is being guided through thermal resistances in series, resulting in a lower effective thermal conductivity when the DE material thermal conductivity is less than the host TE thermal conductivity.

With respect to FIG. 3, finite element computational results are shown for the electrical current vector direction in the TE metamaterial of FIG. 1. The top of the metamaterial 1 is at 0.2 millivolt while the bottom is at 0 volts. The electrical current 5 travels down the length of the monocontinuous thermoelectric material only. The dielectric material has no effect on the electrical and thermoelectrical behavior thus leaving these transport properties unchanged. The result is a complete decoupling of the electrical conductivity, Seebeck coefficient and Peltier coefficient from the effective thermal conductivity of the metamaterial.

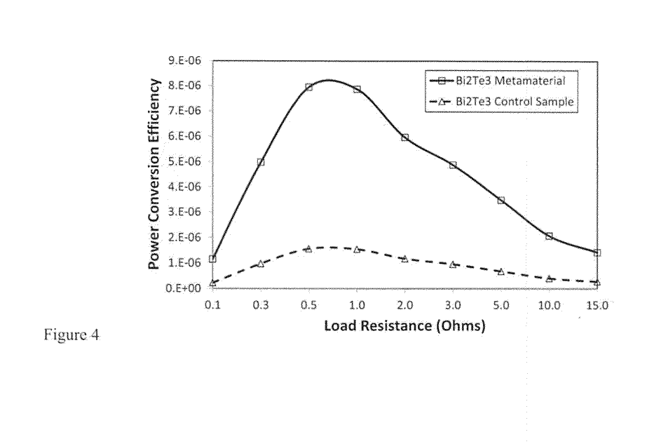

In FIG. 4, power conversion efficiency is shown as a function of load resistance for a Bi₂Te₃ (bismuth telluride) control material and a Bi₂Te₃ metamaterial configured identical to FIG. 1. The metamaterial incorporated a thermoset polymer (DP190-Gray, 3M Co.) as the dielectric material and the effective thermal conductivity x_{eff} was measured at 0.318 W/m-K. Theoretical predictions and finite element computations of x_{eff} resulted in 0.310 W/m-K and 0.319 W/m-K respectively. Consequently, manipulation and control of x_{eff} has been validated experimentally and shows good agreement with theory. The control sample thermal conductivity was measured at 1.62 W/m-K. The Seebeck coefficient and electrical resistivity measurements showed no difference between the control sample and the metamaterial. Throughout the range of measurements, the metamaterial efficiency remained about five times (5×) greater than the control sample. This is due entirely to the decreased x_{eff} which is approximately one fifth (⅕) of the control sample thermal conductivity. Due to the thermal conductivity appearing in the denominator of the efficiency equation, experimental results show excellent agreement with theoretical predictions.

Based on the foregoing descriptions, it can be seen that if an electrical conductor is interfaced with a dielectric material and submitted to a temperature gradient, a heat current will be transported by phonons and electrons within the conductor and phonons only for the dielectric (phonons representing the crystal lattice contribution to heat flow). As a result, the dielectric participates in heat conduction only, but does not take part or contribute to electrical conduction or thermoelectric effects. FIG. 2 shows computational results confirming this phenomenon. The thermal current is represented by the vector arrows in FIG. 2 and clearly follows a downward pattern that results in heat flow through alternating thermoelectric and dielectric layers. If a low thermal conductivity dielectric is selectively placed in a predetermined pattern (for example, FIGS. 1 and 2), thermally in series with the conductor, the overall effective thermal conductance may be substantially lowered.

Using transformation media techniques, computational analysis and theoretical predictions, the conductor and dielectric may be geometrically configured into a metamaterial where the material temperature gradient closely resembles that of any other typical temperature gradient of a regular material placed between hot and cold sources. FIG. 3 shows computational results for electrical current flow. The electrical current is represented by the vector arrows of FIG. 3 and confirms that electrical current flows through the thermoelectric material only. As a result, electrical conductivity and thermoelectric effects of the monocontinuous host material remain unchanged. Therefore, the power factor PF remains unchanged. The result is a thermoelectric metamaterial that behaves electrically and thermoelectrically like a single material, yet thermally as a classical composite with greatly reduced thermal conductivity. The reduced thermal conductivity results in a lower rate of heat flow into the metamaterial. Power conversion efficiency η is expressed as η=Pₒᵤₜ/Qₙ where Pₒᵤₜ is the useable output power of the thermoelectric material and Qᵢₙ is the heat input to the thermoelectric material.

Subsequently, the ability to lower results in lower heat input Qᵢₙ thus raising the efficiency η substantially. FIG. 4 shows experimental results of efficiency measurements on an unaltered bismuth telluride control sample and a bismuth telluride metamaterial. The experimental results agree well with theoretical predictions. While the TE metamaterial used in this initial study was configured as shown in FIG. 1, it should be made clear that there are many different geometrical configurations that may be used to manipulate thermal, electrical and thermoelectrical properties. Therefore, while the 5-fold increase in efficiency is extremely high, there is the distinct likelihood that further research will reveal other metamaterial configurations that exhibit much higher increases in efficiency.

There are two main design parameters for thermoelectric metamaterials, namely geometrical configuration and materials selection. With respect to the geometrical configuration, the shape, volume and material constituents may be fashioned in any number of ways. The manipulation of thermal currents may be intelligently guided by changing the way a material is geometrically configured within a second host material. Specific applications and optimization goals would determine the final overall geometry. The materials selected would include multiple materials combined to form the overall thermoelectric metamaterial. These materials could be dielectrics, semiconductors, semimetals and metals. Combinations of these materials may be joined or interfaced to achieve the desired thermal or electrical current control. There may also be intentional voids which contain no solid material. Each individual material may also be modified to achieve the desired performance. For example, micro or nanoparticles may be mixed, dispersed, interfaced with or combined through solid state chemistry with a primary material. Micro or nanoparticles may also form their own individual material component in the metamaterial. Surface coatings may also be used on some or all constituent materials. These coatings may be electrically conductive or non-electrically conductive. Magnetic materials may also be used in the form of a constituent material, micro/nanomaterial or coating. The materials that make up the final metamaterial may be joined by numerous methods such as epoxy, solder, welding, compression or tension devices or other means.

Thermoelectric materials display the advantage of reverse operation. For example, instead of applying a temperature difference to generate electricity, one may apply electrical power to the thermoelectric to generate hot and cold surfaces. This phenomenon is known as Peltier cooling or heating. Peltier cooling and heating devices are used mainly in specialty applications because their conversion efficiency is typically lower than conventional vapor-compression cooling or heating systems. The metamaterial concept explained in this specification applies equally well to the Peltier cooler or heater. The corresponding figure of merit (Z) will climb substantially as a result of thermal conductivity tuning offered by metamaterials.

All references cited in this specification are herein incorporated by reference as though each reference was specifically and individually indicated to be incorporated by reference. The citation of any reference is for its disclosure prior to the filing date and should not be construed as an admission that the present invention is not entitled to antedate such reference by virtue of prior invention.

It will be understood that each of the elements described above, or two or more together may also find a useful application in other types of methods differing from the type described above. Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention set forth in the appended claims. The foregoing embodiments are presented by way of example only, and the scope of the present invention is to be limited only by the following claims.

The invention claimed is:

1. A thermoelectric metamaterial, comprising:
a plurality of component materials selected from the group consisting of dielectrics, semiconductors, semimetals, and metals; and
wherein the plurality of component materials are placed into contact with one another and arranged in a selected geometrical configuration adapted to achieve a thermal conductivity of the metamaterial that is different from the thermal conductivity of each of the component materials.

2. The metamaterial of claim 1, wherein the figure of merit of the metamaterial is increased relative to the figure of merit of each of the component materials.

3. The metamaterial of claim 1, wherein the power conversion efficiency of the metamaterial is increased relative to each of the component materials.

4. The metamaterial of claim 1, wherein one of the component materials includes nanoparticles of another component material.

5. The metamaterial of claim 1, wherein the geometric configuration of the component materials is rearranged to affect a change in the thermoelectrical properties of the metamaterial.

6. The metamaterial of claim 1, wherein the component materials are placed into contact with one another by mechanical pressure, adhesives, or welding.

7. The metamaterial of claim 1, wherein the component materials have surfaces which are coated with another component material.

8. The metamaterial of claim 1, wherein the thermoelectrical properties of the metamaterial are adjusted to suit a desired application by changing one or more of the following attributes: (a) one of the component materials, (b) the geometric configuration of the component materials, (c) the volume of one or more of the component materials, (d) the absence of a component material at a selected location within the metamaterial, and (e) the manner of contact between the component materials.
